(19) United States
(12) Patent Application Publication
(10) Pub. No.: US 2019/0200488 A1
(43) Pub. Date: Jun. 27, 2019

(54) PLATE-FIN HEAT EXCHANGER SUITABLE FOR RACK-MOUNTABLE COOLING UNIT

(71) Applicant: MCMASTER UNIVERSITY, Hamilton (CA)

(72) Inventors: Souvik Pal, Hamilton (CA); Hosein Moazami-goodarzi, Hamilton (CA); Suvojit Ghosh, Hamilton (CA); Kathryn Thorn, Hamilton (CA); Ishwar K. Puri, Ancaster (CA)

(21) Appl. No.: 16/229,219

(22) Filed: Dec. 21, 2018

Related U.S. Application Data
(60) Provisional application No. 62/609,545, filed on Dec. 22, 2017.

(51) Int. Cl. H05K 7/20

(52) U.S. Cl. CPC H05K 7/20736; H05K 7/20781; H05K 7/20836

(57) ABSTRACT

A plate-fin heat exchanger has a gas coolant flow path whose length is at least twice its thickness, with thickness measured substantially transverse to the gas coolant flow path and substantially transverse to the liquid coolant flow path. The heat exchanger is well suited (although not limited) to use in cooling units for information technology equipment, and can provide substantial cooling while fitting within an enclosure having the same external form factors as standardized rack-mountable ITE configured to fit into standard IT racks. Thus, a cooling unit incorporating the heat exchanger can be installed just as a rack-mountable server is installed. The heat exchanger can fit within an enclosure whose height, measured substantially parallel to the thickness of the heat exchanger and hence substantially transverse to the gas coolant flow path and substantially transverse to the liquid coolant flow path, is a positive integral multiple of RU (1.75 inches).

### CROSS-REFERENCE TO RELATED APPLICATION

The present application claims priority to U.S. Provisional Application No. 62/609,545 filed Dec. 22, 2017, the teachings of which are hereby incorporated by reference.

### TECHNICAL FIELD

The present disclosure relates to cooling units, and more particularly to cooling units suitable for cooling servers and other information technology equipment (ITE).

### BACKGROUND

Almost thirty percent of the power consumption in a data center (DC) is attributable to cooling of information technology equipment (ITE) such as servers and the like. This offers opportunities to reduce DC energy consumption by considering alternatives to traditional cooling methods such as perimeter or “in-row” air-conditioners, which are vulnerable to inherent airflow deficiencies, such as hot air recirculation and cold air bypass. These effects deprive the ITE of the required cold air, thus forming hot spots that can significantly reduce equipment life. Servers and other ITE are typically mounted vertically in stacks within specially designed enclosed racks. The height of rack-mountable ITE is measured in integral multiples of 1.75 inches, i.e., 1 rack unit (RU) is 1.75 inches (about 4.445 cm). Availability of rack space is typically specified in multiples of RU (e.g., a given rack may have 1 RU of available space, 2 RU of available space, 7 RU of available space, etc.).

Rack mounted cooling units (RMCUs), i.e., air-handlers mounted within the same enclosure containing the ITE, overcome some of the above problems because of their proximity to the servers. Additionally, due to the similarity of their form factor with ITEs, the RMCUs can be easily integrated in any empty rack spaces in existing DC facility, thus providing a convenient way to 1) add spot cooling to eliminate hot spots and 2) retrofit existing DCs without impacting existing traditional cooling systems.

However, despite such potential advantages of a fully enclosed rack configuration fitted with RMCUs, the concept has not yet gained sufficient traction. This lack of adoption is potentially attributable to a very low heat removal relative to the space occupied by the cooling unit within the rack. Due to the relatively small cooling capacity of RMCUs, a single rack will require deployment of multiple RMCUs. However, due to their large size, they leave insufficient space in the rack for deploying ITE. In addition, their large size makes them less suitable for retrofitting in existing DCs with a small amount of available empty rack space.

Thus, there are a variety of needs and scenarios that are inadequately addressed by existing cooling technology used for ITE, including:
New racks must be added to an existing facility, however, no additional cooling capacity is available from existing cooling plant;
A need to eliminate local “hot spots” in a particular rack;
New racks need to be added in a facility that lacks additional floor space to install the required additional cooling;
A small or medium business needs a small number of racks, and lacks the resources necessary for setting up traditional raised-floor-based perimeter air conditioning systems, or in-row systems; and
Different racks in a facility need different amounts of cooling, for example because within each rack the cooling load changes dynamically.

### SUMMARY

Broadly speaking, the present disclosure describes a structural configuration for a heat exchanger that enables a compact RMCU with high heat removal capacity. The RMCUs according to the present disclosure can share the same form factors as standardized rack-mountable ITE configured to fit into any standard IT rack, and can be installed just as a rack-mountable server is installed.

In one aspect, the present disclosure is directed to a plate-fin heat exchanger. The heat exchanger comprises a series of spaced-apart, substantially parallel plates, with each plate being spaced from each adjacent plate by a plurality of fins forming fluid flow channel sets of substantially parallel, longitudinally extending fluid flow channels between adjacent plates. The fins and plates being configured and sealed so that a first group of fluid flow channel sets forms a gas coolant flow path through the heat exchanger and a second group of fluid flow channel sets forms a liquid coolant flow path through the heat exchanger substantially transverse to the gas coolant flow path. The heat exchanger has a thickness substantially transverse to the gas coolant flow path and substantially transverse to the liquid coolant flow path, and is characterized in that the gas coolant flow path has a length that is at least twice the thickness. Preferably, the length of the gas coolant flow path is at least 2.5 times the thickness, still more preferably the length of the gas coolant flow path is at least 3 times the thickness, and still even more preferably the length of the gas coolant flow path is about 4 times the thickness.

A cooling unit may comprise a heat exchanger as described above, at least one liquid coolant supply coupling in fluid communication with an inlet to the liquid coolant flow path, at least one liquid coolant exhaust coupling in fluid communication with an outlet from the liquid coolant flow path, and at least one gas flow actuator arranged in fluid communication with the gas coolant flow path and adapted to move coolant gas therethrough.

In some embodiments, at least one liquid flow control valve is in fluid communication with the liquid coolant supply coupling(s) and configured to selectively adjust a flow rate of liquid coolant into the inlet to the liquid coolant flow path. A controller may be communicatively coupled to the liquid flow control valve(s) and configured to drive the liquid flow control valve(s) to selectively adjust a flow rate of liquid coolant into the inlet to the liquid coolant flow path. The controller may be further communicatively coupled to the gas flow actuator(s) and configured to drive the gas flow actuator(s) to selectively increase or decrease flow of the coolant gas through the gas coolant flow path. The cooling unit may further comprise at least one liquid flow meter configured to detect a rate of liquid coolant flow thorough at least one liquid coolant supply coupling(s) and communicatively coupled to the controller.

In some embodiments, the cooling unit further comprises an enclosure wherein the controller, the gas flow actuator(s), the liquid flow control valve(s) and the liquid flow meter(s) are encased within the enclosure. A power supply electrically coupled to the controller, the gas flow actuator, the liquid flow control valve(s) and the liquid flow meter(s) is also encased within the enclosure, and the enclosure includes vents configured to permit the gas flow actuator(s) to draw ambient air into the enclosure, through the heat exchanger and then out of the enclosure. In preferred embodiments, the enclosure has a height that is a positive integral multiple of 1.75 inches (1RU), measured substantially parallel to the thickness of the heat exchanger and hence substantially transverse to the gas coolant flow path and substantially transverse to the liquid coolant flow path.

### BRIEF DESCRIPTION OF THE DRAWINGS

These and other features will become more apparent from the following description in which reference is made to the appended drawings wherein:

FIG. 1 is an exploded view of an illustrative cooling unit according to an aspect of the present disclosure;

FIG. 2 is a detail view of a portion of the cooling unit of FIG. 1 showing an enlarged cross sectional portion of the heat exchanger thereof, taken along the line A-A;

FIG. 3 shows the cooling unit of FIG. 1 mounted in an enclosed standard 19-inch IT rack; and

FIG. 4 shows the cooling unit of FIG. 1 mounted vertically in specially designed brackets within a custom-designed enclosed ITE rack.

### DETAILED DESCRIPTION

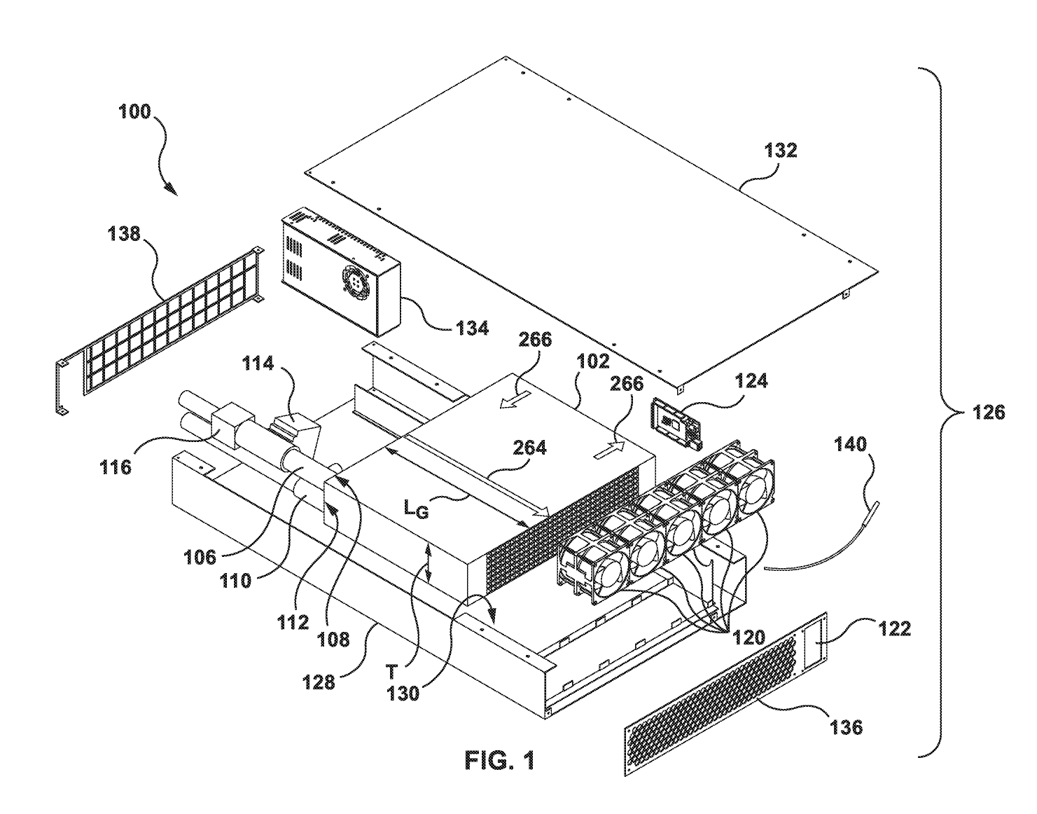

Reference is now made to FIG. 1, which is an exploded view of an illustrative cooling unit according to an aspect of the present disclosure. The cooling unit is denoted generally by reference 100, and comprises a plate-fin type heat exchanger 102, the details of which will be described in greater detail below.

The cooling unit 100 further comprises a liquid coolant supply coupling in the form of a liquid coolant inlet pipe 106, which is in fluid communication with an inlet 108, to a liquid coolant flow path through the heat exchanger 102. The inlet 108 may be coupled in fluid communication with a distribution manifold. The cooling unit 100 still further comprises a liquid coolant exhaust coupling in the form of a liquid coolant exhaust pipe 110 in fluid communication with an outlet 112 from the liquid coolant flow path through the heat exchanger 102. The liquid coolant may be water, or another suitable coolant, for example glycol and dielectric fluids, e.g., 3M™ Novec™ 7100 engineered fluid offered by 3M, having an address at 3M Center, St. Paul, Minn. 55144-1000.

A liquid flow control valve 114, for example a motorized ball valve, is coupled in fluid communication with the liquid coolant inlet pipe 106 and configured to selectively adjust a flow rate of liquid coolant through the liquid coolant inlet pipe 106 into the inlet 108 to the liquid coolant flow path of the heat exchanger 102. A liquid flow meter 116 is also coupled in fluid communication with the liquid coolant inlet pipe 106, and is configured to detect a rate of liquid coolant flow thorough liquid coolant inlet pipe 106 into the inlet 108. The liquid flow meter 116 may be in-line with the liquid flow control valve 114. Optionally, the inlet and outlet liquid temperatures are monitored using two temperature sensors, which may be, for example, inserted into the liquid coolant inlet pipe 106 and the liquid coolant exhaust pipe 110 using compression fittings.

The liquid coolant inlet pipe 106 and liquid coolant exhaust pipe 110 may be coupled to the inlet 108 and outlet 112 of the heat exchanger by a variety of attachment mechanisms, including threaded and quick-disconnect fittings. This enables easy installation and maintenance. While only a single liquid coolant inlet pipe 106 and a single liquid coolant exhaust pipe 110 are shown in the illustrative embodiment, other embodiments may have multiple liquid coolant inlet pipes and/or multiple liquid coolant exhaust pipes.

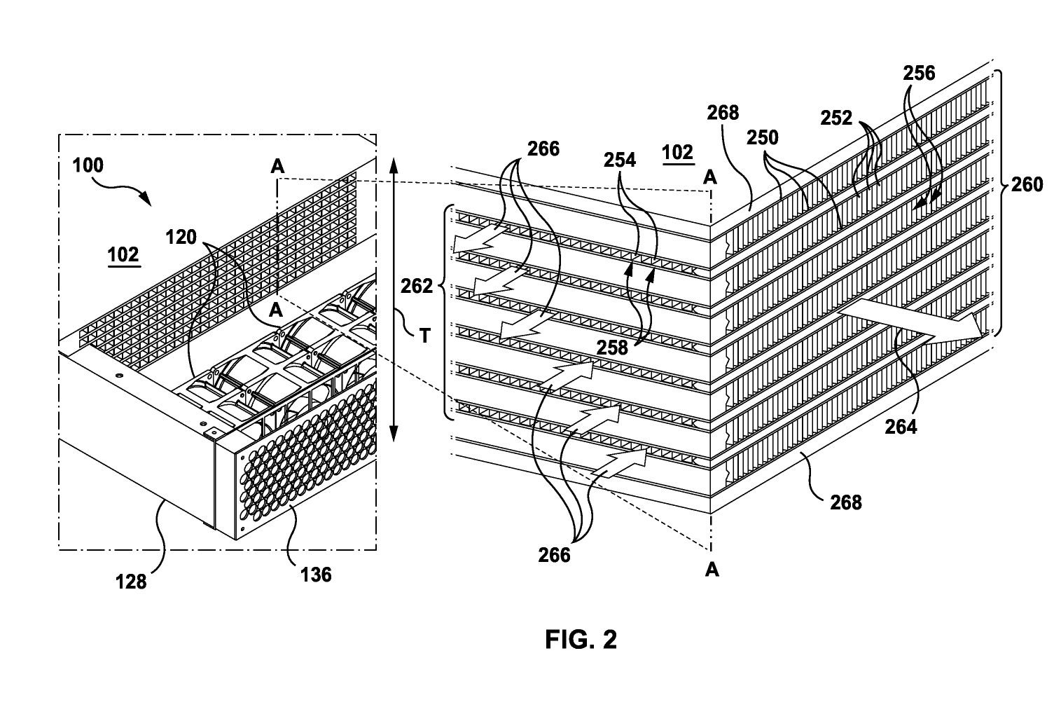

The cooling unit 100 also includes gas flow actuators in the form of fans 120. The fans 120 are arranged in fluid communication with the gas coolant flow path through the heat exchanger 102 and adapted to draw coolant gas through the gas coolant flow path of the heat exchanger 102. In the illustrated embodiment, the fans 120 are high airflow counter-rotating 12V DC axial fans, which drive the air from the back of the heat exchanger 102 to the front thereof. In the illustrated embodiment, the fans 120 are mounted vertically with their plane of rotation of blades being perpendicular to the gas coolant flow path 264 (see FIG. 2) through the heat exchanger 102. Preferably, the fans 120 are mounted in front of the heat exchanger in a row such that each one is at the same fixed distance from the front of the heat exchanger 102, leaving no gap between the sidewalls of the fans 120. The fans 120 are oriented so that the fans 120 pull air through the heat exchanger 102, instead of pushing air through it. While the illustrative embodiment includes five fans 120, in other embodiments more or fewer fans or other gas flow actuators may be used.

An output air temperature/humidity sensor 140 may be disposed at the front of the cooling unit 100 to monitor the temperature of the air exiting the heat exchanger 102; the humidity of this air may also be monitored. One or more intake air temperature/humidity sensors may also be provided.

In the illustrated embodiment, the cooling unit 100 further comprises a controller 124. The controller 124 is communicatively coupled, for example by wires (not shown) or wireless signals, to the liquid flow control valve 114, the liquid flow meter 116 and the fans 120. The controller 124 is configured to drive the liquid flow control valve 114 to selectively adjust a flow rate of liquid coolant into the inlet 108 to the liquid coolant flow path and to drive the fans 120 to selectively increase or decrease flow of the coolant gas through the gas coolant flow path. The liquid flow meter 116 is communicatively coupled to the controller 124 to communicate the rate of liquid coolant flow to the controller 124. The air temperature and humidity sensors, (e.g. output air temperature/humidity sensor 140), are also communicatively coupled to the controller 124.

The illustrated cooling unit further comprises an enclosure 126, which serves as a housing for various components. The enclosure, and hence the cooling unit 100, has external geometric form factors compliant with those of a rack mountable server or similar IT equipment, enabling it to be conveniently installed in existing empty rack spaces in a standard IT rack.

In the illustrated embodiment, the enclosure 126 comprises a main body 128, which 128 is formed monolithically and has a floor and two sidewalls that define a cavity 130 in which components may be mounted, and a cover 132, although other configurations are also contemplated. The controller 124, the fans 120, the liquid flow control valve 114 and the liquid flow meter 116, along with a power supply 134, are encased within the enclosure 126 and suitably sized for such encasement. A front vent grill 136 and rear vent grill 138 are also provided.

The power supply 134 is electrically coupled to the controller 124, the fans 120, the liquid flow control valve 114 and the liquid flow meter 116, for example by wires or other suitable connection so as to provide operating power. In one embodiment, the power supply rated has a rated input of 120/230V, single phase, 60 Hz, which may be supplied from a standard server power supply, and an output of 12V DC, made available through a plurality of terminals for distributing the power to the fans 120, the controller 124 and other components. The electrical coupling of the power supply 134 to the other components may be direct or indirect. For example, the power supply 134 may be directly coupled to the fans 120 to provide power thereto, with the fans 120 also receiving separate control signals from the controller 124. The power supply 134 may be indirectly coupled to the liquid flow control valve 114 and/or the liquid flow meter 116 through the controller 124, without any direct connection. Other configurations are also contemplated. In a preferred embodiment, the power supply 134 can be removed by simply pulling it outward, and replaced by pushing it in place, without having to open the cover 132 of the enclosure 126. Wires connecting the power supply 134 to the various components are omitting from FIG. 1 for simplicity of illustration.

The controller 124 may implement a predictive control system to match the heat load from the ITE, thereby reducing the likelihood and frequency of overcooling (which wastes energy) or undercooling (which places equipment at risk). This may reduce temperature swings in the supplied air, which reduces thermal cycling and may result in increased equipment lifetime. The control of temperature and cooling capacity may be achieved by a combination of adjusting liquid coolant flow rate by partially opening/closing the liquid flow control valve 114 and adjusting air flow rate by changing fan rotational speed through control signals such as pulse width modulation signals. For example, the desired liquid coolant flow rate may be achieved by reading the current liquid coolant flow rate followed by an opening or closing operation to reach a target flow rate based on an equation that describes valve open/close duration and the resulting change in flow rate.

One illustrative implementation employs an adaptive predictive model to track the dynamics of controlled temperature in response to changing input disturbances and determines control actions that minimize both fluctuations in temperature towards reaching the desired state as and the time to reach the desired state. Such a model may track the changes in output air temperature in response to changes in liquid coolant and gas coolant flow rates, and may also take IT workload into account. This allows the controller 126 to predict, ahead of time, the dynamics of output air temperature, and thus make control decisions that reduce fluctuations in output air temperature due to system disturbances, such as rapid load changes. Thus, in some embodiments the controller 124 may execute control actions based on temperatures read by output air temperature/humidity sensor 140 at the front vent grill 136, at a remote server inlet in the cold chamber, an IT workload (in kW) signal obtained from an external energy monitoring system or a combination of any of these. The controller 124 may modulate the fan speed using a pulse width modulation signal and modulate the liquid flow rate through opening/closing of valve, to corresponding values computed by the control algorithm.

Optionally, the controller 124 may include a communication module capable of transmitting monitored system variables, e.g., output air temperature and humidity and liquid flow rate over a wireless network. In one particular embodiment, the communication module communicates through a Wi-Fi network. Preferably, the communication module supports over the air updating such that features and functionalities can be added to control and communication software on the controller 124 through wireless communication. In a particularly preferred embodiment, the communication module is configured to set up its own Wi-Fi connection, which allows the user to connect and configure the cooling unit 100 for first use. Other update and connectivity modalities, for example USB or other wired connectivity are also contemplated. The communication module may be coupled to an electronic display that displays the monitored variables. These may include, for example, any combination of major system variables including controlled temperature, humidity and temperature of air supplied at the front vent grill 136, temperature at the liquid inlet 108 and liquid outlet 112, liquid coolant flow rate, fan speed and an estimated heat removal. A user interface, for example buttons or a touch screen, may be provided to allow users to alter the output air temperature set-point. Optionally, some or all of the sensors noted above may be separate and distinct from the cooling unit 100, and may communicate data to the cooling unit 100 via the communication module, either directly or indirectly, e.g. through one or more sensor management modules, a cooling control unit for the data center, etc. In one embodiment, the controller 124, the communication module and the display form an integral assembly, for example via mechanical fasteners, and shielded at the top and bottom surfaces by an electrically insulating material, with the display aligned with an opening 122 in the front vent grill 136. Preferably, the integral assembly comprising the controller 124 is configured and mounted in the enclosure 126 such that the assembly can be pulled out partially or completely to provide access to all or some of its components, without having to open the cover 132 of the enclosure 126.

In some embodiments, the controller 124, in cooperation with the communication module and the display, may do one or more of (a) store logged data up to a user-defined duration, (2) display the data in the electronic display in real time, (3) host a simple network management protocol (SNMP) server that makes available access to the variables shown on the display and any alarms generated and (4) acts on any user input, for example, a request for changing temperature set-point.

In the illustrated embodiment, the cooling unit 100 uses ambient air as a gas coolant. As such, the enclosure 126 includes vents front and rear vent grills 136, 138 configured to permit the fans 120 to draw air into the enclosure 126 via the rear vent grill 138, through the gas coolant flow path of the heat exchanger 102 and then out of the enclosure via the front vent grill 136. Where output air temperature and humidity sensors are provided, these may be mounted on the inside of the front vent grill 136; output air temperature/humidity sensor 140 is shown. Where intake air temperature sensors are provided, one may be mounted in front of the rear vent grill 138 and one adjacent the back of the heat exchanger 102.

Thus, in one illustrative mode of operation when installed in a server rack, the fans 120 draw in hot air from the back of the rack, heat is removed as the air passes through the gas coolant flow path of the heat exchanger 102, and cooled air is delivered at the front of the rack. The removed heat is transferred to the liquid coolant (e.g. water) flowing through the liquid coolant flow path of the heat exchanger 102. The liquid coolant ultimately releases the heat to an ambient heat rejection system, e.g. from a cooling tower.

Details of the construction of the illustrative heat exchanger 102 will now be described with reference to FIG. 2, which is a detail view of a portion of the cooling unit 100 showing an enlarged cross sectional portion of the heat exchanger 102 thereof, taken along the line A-A.

As noted above, the heat exchanger 102 is a plate-fin heat exchanger 102. As such, the heat exchanger 102 comprises a series of spaced-apart, substantially parallel plates 250. Each plate 250 is spaced from each adjacent plate 250 by a plurality of fins 252, 254 forming sets of substantially parallel, longitudinally extending fluid flow channels 256, 258 between adjacent plates 250. The fins 252, 254 are configured and sealed relative to the plates 250 so that each set of fluid flow channels 256, 258 is substantially transverse to each adjacent set of fluid flow channels 256, 258. As a result of this configuration, there is a first group 260 of fluid flow channel sets and a second group 262 of fluid flow channel sets that is substantially transverse to the first group 260 of fluid flow channel sets. The first group 260 of fluid flow channel sets forms a gas coolant flow path through the heat exchanger 102, denoted by arrow 264, and the second group 262 of fluid flow channel sets forms a liquid coolant flow path through the heat exchanger, denoted by arrows 266. The liquid coolant flow path 266 is substantially transverse to the gas coolant flow path 264. The heat exchanger 102, that is, the plates 250 and the fins 252, 254, may be made from thermally suitable materials, such as aluminum or copper. While copper possesses superior thermal properties relative to aluminum, at time of writing copper is more costly.

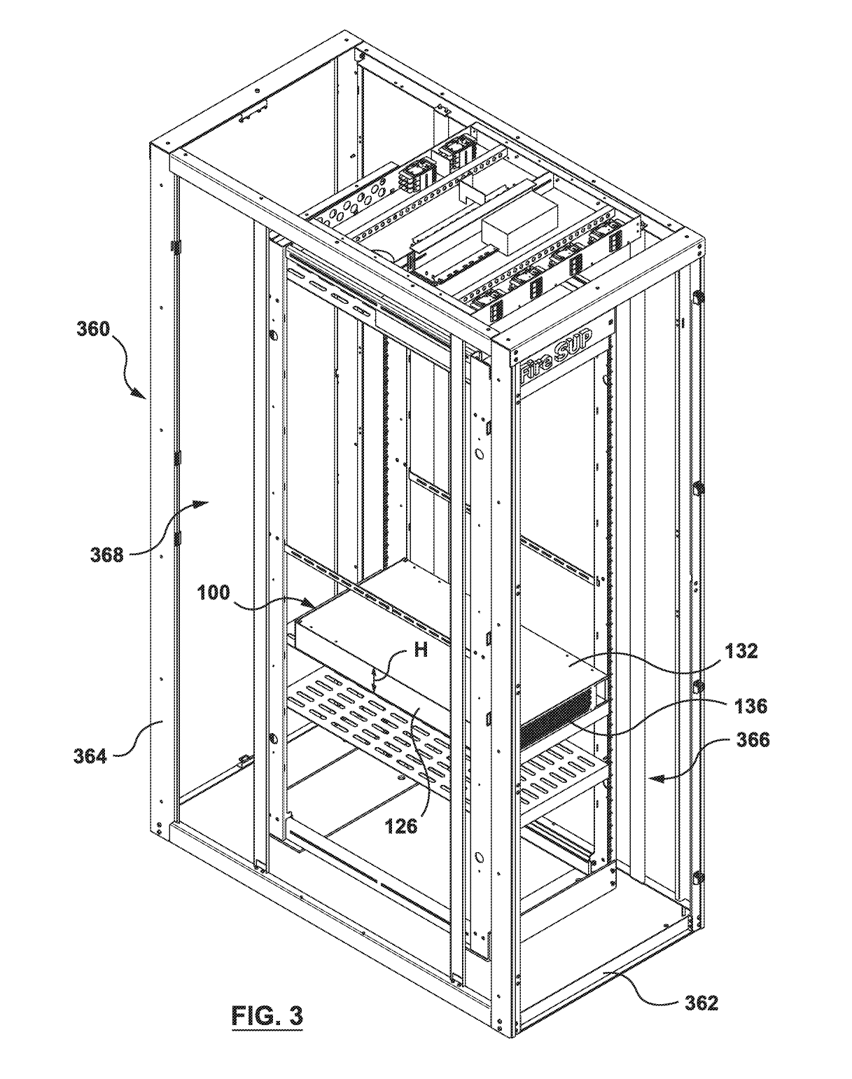

In order to meet RMCU dimensional constraints, the enclosure 126 preferably has a height H (see FIG. 3) that is a positive integral multiple of one RU, that is, 1.75 inches. The height H is measured substantially parallel to the thickness T (see FIG. 1) of the heat exchanger 102 and hence substantially transverse to the gas coolant flow path 264 and substantially transverse to the liquid coolant flow path 266. The term “depth”, as applied to the cooling unit 100, is measured substantially parallel to the gas coolant flow path 264 and the term “width” is measured substantially parallel to the liquid coolant flow path 266. Because the enclosure 126 for the cooling unit 100 is a rack mountable casing that fits within standard IT rack dimensions, the depth and width are constrained. More particularly, the width of the enclosure 126 cannot exceed 17.57 inches (about 44.6 cm), and the depth is constrained by the size of the IT rack. In practice, it has been found that a depth of about 32.5 inches (about 12.8 cm) will fit most standard IT racks, and will accommodate the components while permitting adequate spacing between the components, for example distance between the fans 120 and the heat exchanger 102. Depths greater than about 32.5 inches are also contemplated.

As can be seen in FIG. 1, the heat exchanger 102 has a thickness T, measured substantially transverse to the gas coolant flow path 264 and substantially transverse to the liquid coolant flow path 266. In conventional liquid-to-air heat exchangers, including plate-fin heat exchangers, the “thickness”, that is, the area of cross section substantially transverse to the gas coolant flow path, is relatively large and the length of the gas coolant flow path is small. However, in RMCU applications, where the enclosure 126 is a rack mountable casing that fits within standard IT rack dimensions, the width and depth are limited by the width and depth of a standard IT rack. Additionally, by design, the thickness is constrained because the height of the cooling unit, including the enclosure 126, heat exchanger 102 and other components inside, must be as small as possible in order to be compact, and is further constrained by the preference that the height of the cooling unit be an integral multiple of RU. The reason that integral multiples of RU are preferable is that this will enable the cooling unit 100 to fit a standard IT rack without wasted space or unrealized cooling capacity. If the enclosure were, say, 1.5 RU in height, it would still usurp two slots in the rack (a standard server would not fit the unoccupied “half slot”) while providing less cooling capacity than a suitably configured cooling unit of 2 RU in height. Thus, integral multiples of RU are preferred. In some embodiments, as shown in FIG. 3, the height H is a single RU (1.75 inches); in other embodiments the height may be 2 RU (3.5 inches) or a greater positive integral multiple of one RU. Given currently commercially available fans and their size-to-airflow ratio, a height H of 2RU or more is presently preferable, with a height of 2RU being particularly preferred.

The above-described constraints can be characterized as “high aspect ratio” constraints. These makes it a non-trivial design problem, and as such it becomes non-obvious to simply modify existing RMCU designs to come up with a configuration that satisfy all geometrical constraints yet produce a satisfactory cooling performance. Significantly, the length-to-thickness ratio for traditional liquid-to-air heat exchangers is significantly less than one, which is simply incompatible with the design constraints of an RMCU.

The heat exchanger 102 according to the present disclosure is a compact plate-fin type cross flow heat exchanger, providing a length-to-thickness ratio compatible with RMCU dimensional constraints. Importantly, and in fact critically, as shown in FIG. 1 the gas coolant flow path 264 has a length L_{G} that is at least twice the thickness T of the heat exchanger 102 substantially transverse to the gas coolant flow path 264 and substantially transverse to the liquid coolant flow path 266. This high length-to-thickness aspect ratio is critical to the ability of the heat exchanger 102 to provide high heat transfer while being able to fit within the design constraints for an RMCU. Preferably, the length L_{G} of the gas coolant flow path is at least 2.5 times the thickness T. Still even more preferably, the length L_{G} of the gas coolant flow path is at least three times the thickness T. Yet still even more preferably, the length L_{G} of the gas coolant flow path is about four times the thickness T. By adjusting the depth and the pitch of the fins 252, 254 for the fluid flow channels 256, 258, high heat transfer area at a low pressure drop (which translates to a high airflow) may be achieved.

In the illustrated embodiment, each of the plates 250 have a thickness (parallel to the thickness T of the heat exchanger 102) of about 0.69 mm (about 0.0271 inch). The space between the adjacent pairs of plates 250 between which the first group 260 of fluid flow channel sets (defining the gas coolant flow path 264) is about 8.0 mm (about 0.315 inch). The space between the adjacent pairs of plates 250 between which the second group 262 of fluid flow channel sets (defining the liquid coolant flow path 266) is about 2.0 mm (about 0.0787 inch). There are seven fluid flow channel sets in the first group 260 (defining the gas coolant flow path 264) and six fluid flow channel sets the second group 262 (defining the liquid coolant flow path 266). The fins 252, 254 are formed by continuous crenellated sheets having a thickness of about 0.2 mm (about 0.00787 inch). The pitch, that is the width of each crenel and hence the distance between each merlon, is about 2.5 mm (about 0.0984) for the fins 252 forming the first group 260 of fluid flow channel sets (defining the gas coolant flow path 264) and is about 3.5 mm (about 0.138 inch) for the fins 254 forming the second group 262 of fluid flow channel sets (defining the liquid coolant flow path 266). The length of the plates 250, and therefore the length L_{G} of the gas flow path, is about 31.7 cm (about 12.48 inches) and the width of the plates 250 is about 34.6 cm (about 13.6 inch). The thickness T of the heat exchanger 102, including the upper and lower sealing plates 268 each about 1.67 mm (about 0.06574 inch), is about 81 mm (about 3.18 inch). Thus, in the illustrated embodiment, the length L_{G} of the gas flow path is 3.91 times the thickness T of the heat exchanger.

The fans 120 are subject to a similar constraint to that of the heat exchanger 102, in that they must fit within the enclosure 126, which has a height H (including the thickness of the floor of the main body 128 and the thickness of the cover 132) that is constrained to be an integral multiple of RU.

The configuration of the heat exchanger 102, and the selection of the type and number of fans 120, may be determined through rigorous scientific optimization exercises to maximize the airflow and heat removal rate through the system. In the illustrated embodiment, the fans 120 may be, for example, Denki Model No. 9CRB0812P8G001 or Delta Model No. GFM0812DUB7S offered by Sanyo Electric Co., Ltd. For instance, one embodiment of the system can remove 5 kW of heat and output air at a rate of 600 cubic feet per minute (dm). The specific design of the heat exchanger allows for a high airflow through the cooling unit, enabling cooling density of 2.5 kW/RU.

Reference is now made to FIG. 3, which shows the cooling unit 100 of FIG. 1 mounted in a standard 19-inch (about 48.26 cm) IT rack, denoted by reference 360. The rack 360 has a front door 362 and a back door 364, isolating the air inside from the environment where the rack is kept. The space 366 between the front door 362 and the front intake grills of the servers and/or other ITE (not shown) functions as a fully contained front cold chamber 366, and the space 368 between the back door 364 and the back exhaust grills of the servers and/or other ITE serves as a fully contained rear hot chamber 368. The cooling unit 100 can be installed and operated in a fully enclosed rack such as the rack 360 in FIG. 3, without any air exchange from the environment in which the rack 360 is kept. The front vent grill 136 of the cooling unit 100 faces and is exposed to the front cold chamber 366 and the rear vent grill 138 faces and is exposed to the rear hot chamber 368. The servers and/or other ITE produce substantial heat during operation. Cold air from the front cold chamber 366 flows through the servers and/or other ITE, picks up the heat from the CPU(s) and other heat generating electronics inside and is thereby heated, and emerges into the rear hot chamber 368. The cooling unit 100 then draws in this heated air through the rear vent grill 138, after which it passes through the heat exchanger 102, where the heated air transfers heat to the liquid coolant moving through the heat exchanger 102, which in turn transfers the heat out of the rack and rejects it to an ambient heat rejection system. The cooled air then continues through the cooling unit 100 and is delivered to the front cold chamber 366.

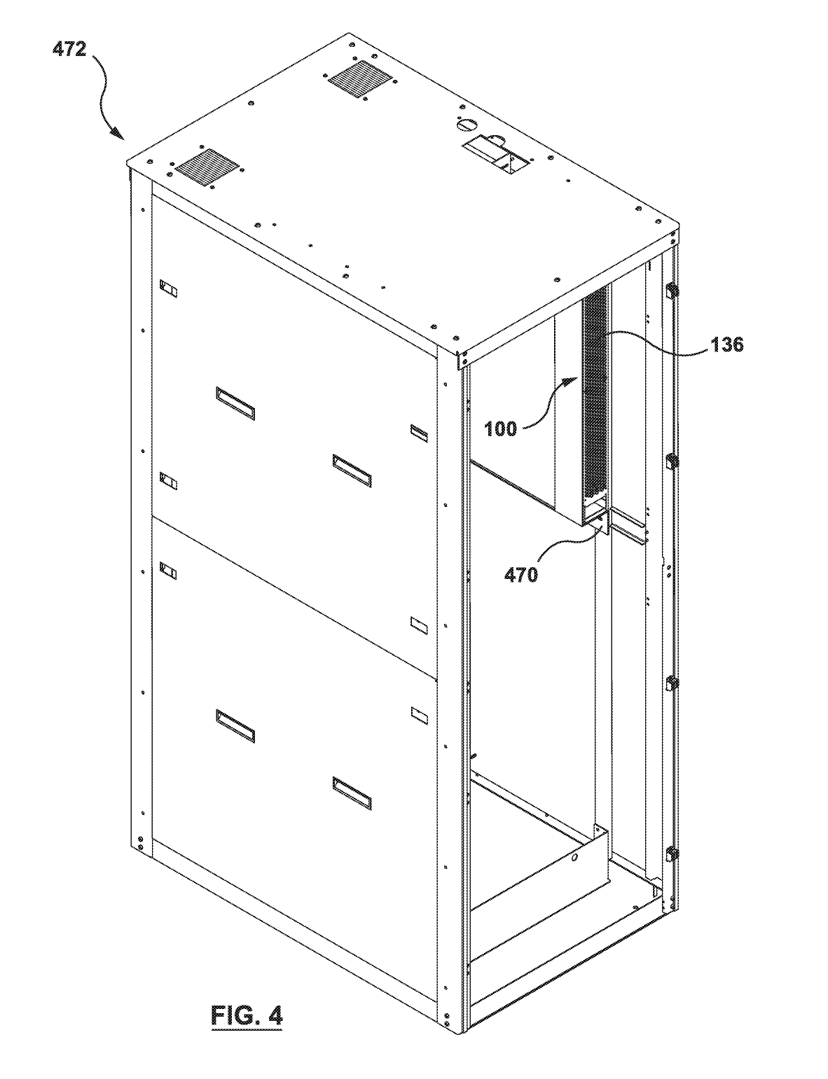

As can be seen, in FIG. 3 the cooling unit 100 is positioned horizontally in the rack 360, mounted in the same way, and using the same mounting hardware, as a server or other ITE would be. This is merely one illustrative configuration, and FIG. 4 shows an alternative configuration. In FIG. 4, cooling units 100 have been mounted vertically in specially designed brackets 470 within a custom-designed enclosed ITE rack 472. The custom-designed enclosed ITE rack 470 is similar to the standard ITE rack 360 in FIG. 3, with the same internal hardware for mounting standard size servers and/or other ITE, but is wider to accommodate the cooling units 100.

Accordingly, FIGS. 3 and 4 illustrate a method for cooling ITE. The method comprises placing a cooling unit 102 in an enclosed ITE rack, wherein the cooling unit incorporates a plate-fin heat exchanger whose gas coolant flow path has a length that is at least twice the thickness of the heat exchanger, measured substantially transverse to the gas coolant flow path and substantially transverse to the liquid coolant flow path.

Certain illustrative embodiments have been described by way of example. It will be apparent to persons skilled in the art that a number of variations and modifications can be made without departing from the scope of the claims.

What is claimed is:

1. A plate-fin heat exchanger, comprising:
a series of spaced-apart, substantially parallel plates;
each plate being spaced from each adjacent plate by a plurality of fins forming sets of substantially parallel, longitudinally extending fluid flow channels between adjacent plates;
the fins being configured and sealed relative to the plates so that each set of fluid flow channels is substantially transverse to each adjacent set of fluid flow channels whereby there is a first group of fluid flow channel sets and a second group of fluid flow channel sets that is substantially transverse to the first group of fluid flow channel sets;
the first group of fluid flow channel sets forming a gas coolant flow path through the heat exchanger;
the second group of fluid flow channel sets forming a liquid coolant flow path through the heat exchanger substantially transverse to the gas coolant flow path;
the heat exchanger having a thickness substantially transverse to the gas coolant flow path and substantially transverse to the liquid coolant flow path;
characterized in that:
the gas coolant flow path has a length that is at least twice the thickness substantially transverse to the gas coolant flow path and substantially transverse to the liquid coolant flow path.

2. The heat exchanger of claim 1, further characterized in that the length of the gas coolant flow path is at least 2.5 times the thickness substantially transverse to the gas coolant flow path and substantially transverse to the liquid coolant flow path.

3. The heat exchanger of claim 1, further characterized in that the length of the gas coolant flow path is at least 3 times the thickness substantially transverse to the gas coolant flow path and substantially transverse to the liquid coolant flow path.

4. A cooling unit, comprising:
a heat exchanger according to claim 1;
at least one liquid coolant supply coupling in fluid communication with an inlet to the liquid coolant flow path;
at least one liquid coolant exhaust coupling in fluid communication with an outlet from the liquid coolant flow path;
at least one gas flow actuator arranged in fluid communication with the gas coolant flow path and adapted to draw coolant gas therethrough.

5. The cooling unit of claim 4, further comprising:
at least one liquid flow control valve in fluid communication with the at least one liquid coolant supply coupling and configured to selectively adjust a flow rate of liquid coolant into the inlet to the liquid coolant flow path.

6. The cooling unit of claim 5, further comprising:
a controller communicatively coupled to the at least one liquid flow control valve and configured to drive the at least one liquid flow control valve to selectively adjust a flow rate of liquid coolant into the inlet to the liquid coolant flow path.

7. The cooling unit of claim 6, wherein the controller is further communicatively coupled to the at least one gas flow actuator and configured to drive the at least one gas flow actuator to selectively increase or decrease flow of the coolant gas through the gas coolant flow path.

8. The cooling unit of claim 7, further comprising at least one liquid flow meter configured to detect a rate of liquid coolant flow thorough the at least one liquid coolant supply coupling and communicatively coupled to the controller.

9. The cooling unit of claim 8, further comprising an enclosure wherein:
the controller, the at least one gas flow actuator, the at least one liquid flow control valve and the at least one liquid flow meter are encased within the enclosure;
a power supply electrically coupled to the controller, the at least one gas flow actuator, the at least one liquid flow control valve and the at least one liquid flow meter is also encased within the enclosure; and
the enclosure includes vents configured to permit the at least one gas flow actuator to draw ambient air into the enclosure, through the heat exchanger and then out of the enclosure.

10. The cooling unit of claim 9, wherein the enclosure has a height that is a positive integral multiple of 1.75 inches, measured substantially parallel to the thickness of the heat exchanger and hence substantially transverse to the gas coolant flow path and substantially transverse to the liquid coolant flow path.

11. A plate-fin heat exchanger, comprising:
a series of spaced-apart, substantially parallel plates;
each plate being spaced from each adjacent plate by a plurality of fins forming fluid flow channel sets of substantially parallel, longitudinally extending fluid flow channels between adjacent plates;
the fins and plates being configured and sealed so that:
a first group of fluid flow channel sets forms a gas coolant flow path through the heat exchanger;
a second group of fluid flow channel sets forms a liquid coolant flow path through the heat exchanger substantially transverse to the gas coolant flow path;
the heat exchanger having a thickness substantially transverse to the gas coolant flow path and substantially transverse to the liquid coolant flow path;
characterized in that:
the gas coolant flow path has a length that is at least twice the thickness substantially transverse to the gas coolant flow path and substantially transverse to the liquid coolant flow path.

12. The heat exchanger of claim 11, further characterized in that the length of the gas coolant flow path is at least 2.5 times the thickness substantially transverse to the gas coolant flow path and substantially transverse to the liquid coolant flow path.

13. The heat exchanger of claim 11, further characterized in that the length of the gas coolant flow path is at least 3 times the thickness transverse to the gas coolant flow path and substantially transverse to the liquid coolant flow path.

14. A cooling unit, comprising:
a heat exchanger according to claim 11;
at least one liquid coolant supply coupling in fluid communication with an inlet to the liquid coolant flow path;
at least one liquid coolant exhaust coupling in fluid communication with an outlet from the liquid coolant flow path;
at least one gas flow actuator arranged in fluid communication with the gas coolant flow path and adapted to draw coolant gas therethrough.

15. The cooling unit of claim 14, further comprising:
at least one liquid flow control valve in fluid communication with the at least one liquid coolant supply coupling and configured to selectively adjust a flow rate of liquid coolant into the inlet to the liquid coolant flow path.

16. The cooling unit of claim 15, further comprising:
a controller communicatively coupled to the at least one liquid flow control valve and configured to drive the at least one liquid flow control valve to selectively adjust a flow rate of liquid coolant into the inlet to the liquid coolant flow path.

17. The cooling unit of claim 16, wherein the controller is further communicatively coupled to the at least one gas flow actuator and configured to drive the at least one gas flow actuator to selectively increase or decrease flow of the coolant gas through the gas coolant flow path.

18. The cooling unit of claim 17, further comprising at least one liquid flow meter configured to detect a rate of liquid coolant flow thorough the at least one liquid coolant supply coupling and communicatively coupled to the controller.

19. The cooling unit of claim 18, further comprising an enclosure wherein:
the controller, the at least one gas flow actuator, the at least one liquid flow control valve and the at least one liquid flow meter are encased within the enclosure;
a power supply electrically coupled to the controller, the at least one gas flow actuator, the at least one liquid flow control valve and the at least one liquid flow meter is also encased within the enclosure; and
the enclosure includes vents configured to permit the at least one gas flow actuator to draw ambient air into the enclosure, through the heat exchanger and then out of the enclosure.

20. The cooling unit of claim 19, wherein the enclosure has a height that is a positive integral multiple of 1.75 inches, measured substantially parallel to the thickness of the heat exchanger and hence substantially transverse to the gas coolant flow path and substantially transverse to the liquid coolant flow path.
